(19) United States
(12) Patent Application Publication
(10) Pub. No.: US 2009/0166858 A1
(43) Pub. Date: Jul. 2, 2009

(54) LGA SUBSTRATE AND METHOD OF MAKING SAME

(76) Inventors: Omar J. Bchir, Phoenix, AZ (US); Munehiro Toyama, Tsukubashi (JP); Charan Gurumurthy, Higley, AZ (US); Tamil Selvy Selvamuniandy, Chandler, AZ (US)

Correspondence Address: INTEL CORPORATION;c/o CPA Global, P.O. BOX 52050, MINNEAPOLIS, MN, 55402, US

(21) Appl. No.: 11/966,876

(22) Filed: Dec. 28, 2007

(51) Int. Cl. H01L 23/488; H01L 21/44

(52) U.S. Cl. 257/737; 438/614; 257/E21.476; 257/E23.023

(57) ABSTRACT

An LGA substrate includes a core (110), having build-up dielectric material (150), at least one metal layer (125), and solder resist (155) formed thereon, an electrically conductive land grid array pad (120) electrically connected to the metal layer, a nickel layer (121) on the electrically conductive land grid array pad, a palladium layer (122) on the nickel layer, and a gold layer (123) on the palladium layer.

### FIELD OF THE INVENTION

The disclosed embodiments of the invention relate generally to land grid array (LGA) substrates for microelectronic devices, and relate more particularly to surface finish materials for use with LGA substrates.

### BACKGROUND OF THE INVENTION

Many microelectronic systems include a microprocessor or other integrated circuit device that must be electrically integrated with a printed circuit board or another component of the microelectronic system. Such systems may make use of a socket interface that receives the integrated circuit device and forms an electrical connection with it. Various socket types exist, including those based on architectures such as ball grid array (BGA), pin-grid array (PGA), and land grid array (LGA).

BGA and PGA packaging use solder balls and pins, respectively, to form a connection with a printed circuit board. LGA packaging, in contrast, has no such features on the substrate; in place of pins or solder balls are pads, often of gold-plated material on a metal stackup including copper, that contact electrically conductive features (i.e., LGA socket pins) in the socket mounted on the printed circuit board. In order to decrease contact resistance between the LGA unit and the socket, LGA substrates are treated with a surface finish comprising layers of nickel and thick gold. Presently, some LGA substrates use an electroless nickel-immersion gold-electroless gold (ENIG+EG) surface finish, which provides a gold layer sufficient for suitably low contact resistance between socket and package. However, the ENIG+EG surface finish suffers from high cost and can suffer from low mean time to failure (MTTF) in first level interconnect (FLI) electromigration bias testing, depending on the metal stackup in the solder joint.

### BRIEF DESCRIPTION OF THE DRAWINGS

The disclosed embodiments will be better understood from a reading of the following detailed description, taken in conjunction with the accompanying figures in the drawings in which:

FIG. 1 is a side elevational view of an LGA substrate according to an embodiment of the invention;

FIG. 2 is a flowchart illustrating a method of making an LGA substrate according to an embodiment of the invention; and

FIG. 3 is a flowchart illustrating a method for making an LGA substrate according to a different embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, an LGA substrate comprises a core having build-up dielectric material, at least one metal layer, and solder resist formed thereon, an electrically conductive land grid array pad electrically connected to the metal line, a nickel (Ni) layer on the electrically conductive land grid array pad, a palladium (Pd) layer on the nickel layer, and a gold (Au) layer on the palladium layer.

Replacing the current ENIG+EG surface finish on LGA substrates with NiPdAu increases the maximum current carrying capability of certain critical power delivery nets in the substrate (depending on metallurgy stackup) while providing a significant reduction in unit cost due to elimination of the thick, expensive EG layer from the substrate manufacturing process. FLI electromigration MTTF can also be significantly improved, depending on the metallurgy stackup.

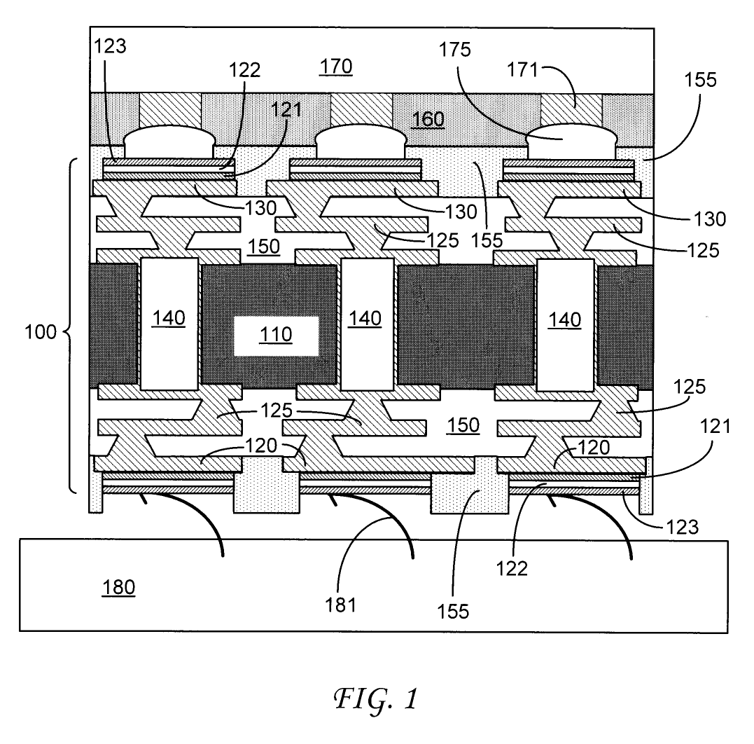

Referring now to the drawings, FIG. 1 is a side elevational view of an LGA substrate 100 according to an embodiment of the invention. As illustrated in FIG. 1, LGA substrate 100 comprises a core 110 having a build-up dielectric material 150, metal layers 125, and solder resist 155 formed thereon, an electrically conductive land grid array pad 120 (such as a copper land or the like) electrically connected to a metal layer 125, a nickel layer 121 on electrically conductive land grid array pad 120, a palladium layer 122 on nickel layer 121, and a gold layer 123 on palladium layer 122.

LGA substrate 100 connects a die 170 having electrically conductive (e.g., copper) columns 171 to a socket 180 having pins 181 that contact gold layer 123. (In a non-illustrated embodiment, electrically conductive columns 171 are replaced by solder under bump metallization (UBM) or the like.) Solder bumps 175 electrically connect die 170 to controlled collapse chip connect (C4) pads 130 that are electrically connected to metal layers 125. Core 110 contains plugs 140 surrounded by a sheath of copper or other electrically conductive material connecting C4 pads 130 to land grid array pads 120. Like land grid array pad 120, C4 pads 130 are coated with nickel layer 121, palladium layer 122 above nickel layer 121, and gold layer 123 above palladium layer 122. It should be noted here that each individual metal layer in the NiPdAu surface finish stack is, in at least one embodiment, formed on land grid array pad 120 and C4 pad 130 simultaneously; hence the use of identical reference numerals for Ni, Pd, and Au layers on those features of LGA substrate 100 in FIG. 1. LGA substrate 100 further comprises underfill material 160.

In one embodiment, nickel layer 121 has a thickness of between approximately 5 micrometers and approximately 10 micrometers. In the same or another embodiment, palladium layer 122 has a thickness of between approximately 0.01 micrometers and approximately 0.1 micrometers and in the same or another embodiment, gold layer 123 has a thickness of between approximately 0.01 micrometers and approximately 0.5 micrometers.

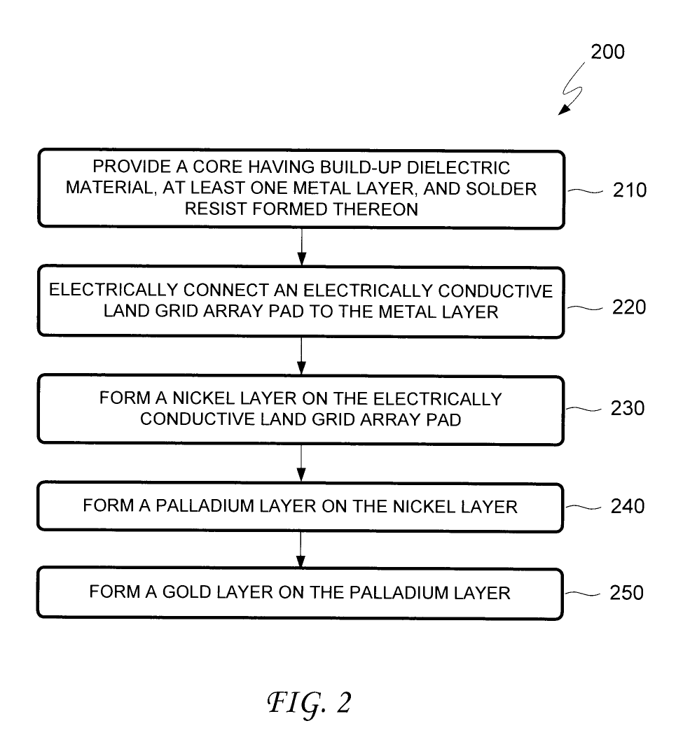

FIG. 2 is a flowchart illustrating a method 200 of making an LGA substrate according to an embodiment of the invention. A step 210 of method 200 is to provide a core having build-up dielectric material, at least one metal layer, and solder resist formed thereon. As an example, the core can be similar to core 110 that is shown in FIG. 1. As another example, the build-up dielectric material, the metal layer, and the solder resist can be similar to, respectively, build-up dielectric material 150, metal layer 125, and solder resist 155, all of which are shown in FIG. 1.

A step 220 of method 200 is to electrically connect an electrically conductive land grid array pad to the metal layer. As an example, the land grid array pad can be similar to land grid array pad 120 that is shown in FIG. 1.

A step 230 of method 200 is to form a nickel layer on the electrically conductive land grid array pad. As an example, the nickel layer can be similar to nickel layer 121 that is shown in FIG. 1. In one embodiment, step 230 comprises plating the nickel layer using an electroless plating process.

A step 240 of method 200 is to form a palladium layer on the nickel layer. As an example, the palladium layer can be similar to palladium layer 122 that is shown in FIG. 1. In one embodiment, step 240 comprises plating the palladium layer using an electroless plating process. An electroless palladium bath deposits a thin layer of palladium onto the nickel layer using an oxidation-reduction reaction in which a reducing agent provides electrons to positively-charged palladium ions from the plating solution. In another embodiment, step 240 comprises plating the palladium layer using an immersion plating process. In this reaction, palladium atoms are deposited only onto the exposed nickel surface in a chemical displacement reaction. Immersion plating is a replacement process, meaning that the top layer of the material being plated is replaced with a layer of the plating metal. This limits the thickness of the plated layer because the immersion process is self-limiting and stops once the original metal surface is no longer exposed.

A step 250 of method 200 is to form a gold layer on the palladium layer. As an example, the gold layer can be similar to gold layer 123 that is shown in FIG. 1. In one embodiment, step 250 comprises plating the gold layer using an immersion plating process. In another embodiment, step 250 comprises plating the gold layer using an electroless plating process. In another embodiment, step 250 comprises plating the gold layer using both an immersion plating process and an electroless plating process.

The choice of plating process or processes may depend at least to some degree on the desired thickness of the gold layer. If the desired thickness of the plated layer is thicker than can be obtained with an immersion plating technique, other methods must be used instead of, or in addition to, the immersion plating. It should be pointed out that even if both immersion plating and electroless plating are used the result is a single layer of the substance being plated (whether gold or another material); no boundary between what is plated using the immersion technique and what is plated using the electroless technique can typically be detected.

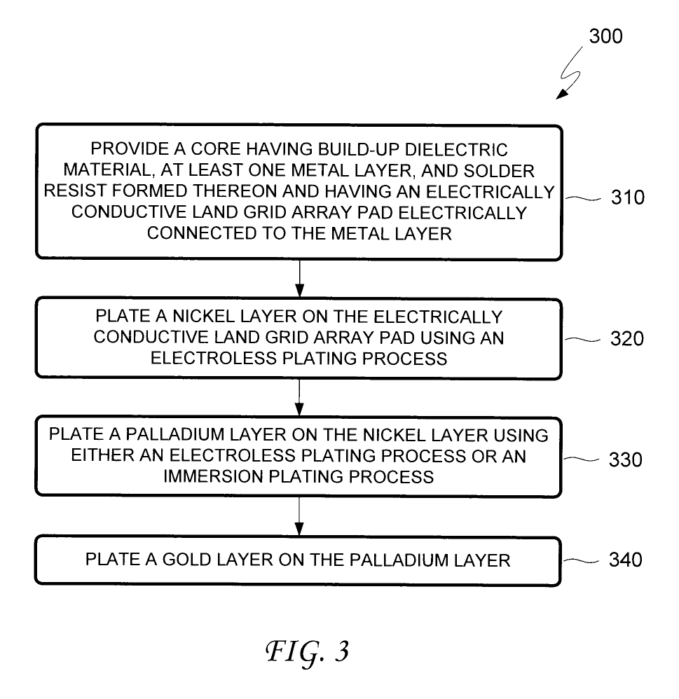

FIG. 3 is a flowchart illustrating a method 300 for making an LGA substrate according to a different embodiment of the invention. A step 310 of method 300 is to provide a core having build-up dielectric material, at least one metal layer, and solder resist formed thereon and having an electrically conductive land grid array pad electrically connected to the metal layer. As an example, the core, the build-up dielectric material, the metal layer, the solder resist, and the electrically conductive land grid array pad can be similar to, respectively, core 110, build-up dielectric material 150, metal layer 125, solder resist 155, and land grid array pad 120, all of which are shown in FIG. 1.

A step 320 of method 300 is to plate a nickel layer on the electrically conductive land grid array pad using an electroless plating process. As an example, the nickel layer can be similar to nickel layer 121 that is shown in FIG. 1. In one embodiment, step 320 comprises causing the nickel layer to have a thickness of between approximately 5 micrometers and approximately 10 micrometers.

A step 330 of method 300 is to plate a palladium layer on the nickel layer using either an electroless plating process or an immersion plating process. As an example, the palladium layer can be similar to palladium layer 122 that is shown in FIG. 1. In one embodiment, step 330 comprises causing the palladium layer to have a thickness of between approximately 0.01 micrometers and approximately 0.1 micrometers.

A step 340 of method 300 is to plate a gold layer on the palladium layer. As an example, the gold layer can be similar to gold layer 123 that is shown in FIG. 1. In one embodiment, step 340 comprises making use of an immersion plating process. In another embodiment, step 340 comprises making use of an electroless plating process. In another embodiment, step 340 comprises making use of both an immersion plating process and an electroless plating process. In one embodiment, step 340 comprises causing the gold layer to have a thickness of between approximately 0.01 micrometers and approximately 0.5 micrometers.

A relationship between the percentage of LGA units with fails and time varies depending on the type of surface finish being used. It has been found that a NiPdAu surface finish according to embodiments of the invention provides as much as a 40 percent improvement in electromigration MTTF over what is possible with the standard ENIG+EG surface finish, for a specific C4 solder metallurgy. The amount of the improvement depends in part on the type of solder used with the NiPdAu surface finish.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the LGA substrate and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. An LGA substrate comprising:
a core having build-up dielectric material, at least one metal layer, and solder resist formed thereon;
an electrically conductive land grid array pad electrically connected to the metal layer;
a nickel layer on the electrically conductive land grid array pad;
a palladium layer on the nickel layer; and
a gold layer on the palladium layer.

2. The LGA substrate of claim 1 wherein:
the nickel layer has a thickness of between approximately 5 micrometers and approximately 10 micrometers.

3. The LGA substrate of claim 1 wherein:
the palladium layer has a thickness of between approximately 0.01 micrometers and approximately 0.1 micrometers.

4. The LGA substrate of claim 1 wherein:
the gold layer has a thickness of between approximately 0.01 micrometers and approximately 0.5 micrometers.

5. The LGA substrate of claim 1 wherein:
the electrically conductive land grid array pad comprises a copper land.

6. The LGA substrate of claim 5 wherein:
the nickel layer has a thickness of no greater than approximately 10 micrometers;
the palladium layer has a thickness of no greater than approximately 0.1 micrometers; and
the gold layer has a thickness of no greater than approximately 0.5 micrometers.

7. A method of making an LGA substrate, the method comprising:
providing a core having build-up dielectric material, at least one metal layer, and solder resist formed thereon;
electrically connecting an electrically conductive land grid array pad to the metal layer;
forming a nickel layer on the electrically conductive land grid array pad;
forming a palladium layer on the nickel layer; and
forming a gold layer on the palladium layer.

8. The method of claim 7 wherein:
forming the nickel layer comprises plating the nickel layer using an electroless plating process.

9. The method of claim 7 wherein:
forming the palladium layer comprises plating the palladium layer using an electroless plating process.

10. The method of claim 7 wherein:
forming the palladium layer comprises plating the palladium layer using an immersion plating process.

11. The method of claim 7 wherein:
forming the gold layer comprises plating the gold layer using an immersion plating process.

12. The method of claim 11 wherein:
forming the nickel layer comprises plating the nickel layer using an electroless plating process; and
forming the palladium layer comprises plating the palladium layer using an electroless plating process.

13. The method of claim 11 wherein:
forming the nickel layer comprises plating the nickel layer using an electroless plating process; and
forming the palladium layer comprises plating the palladium layer using an immersion plating process.

14. The method of claim 7 wherein:
forming the gold layer comprises plating the gold layer using an electroless plating process.

15. The method of claim 14 wherein:
forming the nickel layer comprises plating the nickel layer using an electroless plating process; and
forming the palladium layer comprises plating the palladium layer using an electroless plating process.

16. The method of claim 14 wherein:
forming the nickel layer comprises plating the nickel layer using an electroless plating process; and
forming the palladium layer comprises plating the palladium layer using an immersion plating process.

17. The method of claim 7 wherein:
forming the gold layer comprises plating the gold layer using an immersion plating process and an electroless plating process.

18. The method of claim 17 wherein:
forming the nickel layer comprises plating the nickel layer using an electroless plating process; and
forming the palladium layer comprises plating the palladium layer using an electroless plating process.

19. The method of claim 17 wherein:
forming the nickel layer comprises plating the nickel layer using an electroless plating process; and
forming the palladium layer comprises plating the palladium layer using an immersion plating process.

20. A method of making an LGA substrate, the method comprising:
providing a core having build-up dielectric material, at least one metal layer, and solder resist formed thereon and having an electrically conductive land grid array pad electrically connected to the metal layer;
plating a nickel layer on the electrically conductive land grid array pad using an electroless plating process;
plating a palladium layer on the nickel layer using either an electroless plating process or an immersion plating process; and
plating a gold layer on the palladium layer.

21. The method of claim 20 wherein:
plating the gold layer comprises making use of an immersion plating process.

22. The method of claim 21 wherein:
plating the nickel layer comprises causing the nickel layer to have a thickness of between approximately 5 micrometers and approximately 10 micrometers;
plating the palladium layer comprises causing the palladium layer to have a thickness of between approximately 0.01 micrometers and approximately 0.1 micrometers; and
plating the gold layer comprises causing the gold layer to have a thickness of between approximately 0.01 micrometers and approximately 0.5 micrometers.

23. The method of claim 20 wherein:
plating the gold layer comprises making use of an electroless plating process.

24. The method of claim 23 wherein:
plating the nickel layer comprises causing the nickel layer to have a thickness of between approximately 5 micrometers and approximately 10 micrometers;
plating the palladium layer comprises causing the palladium layer to have a thickness of between approximately 0.01 micrometers and approximately 0.1 micrometers; and
plating the gold layer comprises causing the gold layer to have a thickness of between approximately 0.01 micrometers and approximately 0.5 micrometers.

25. The method of claim 20 wherein:
plating the gold layer comprises making use of both an immersion plating process and an electroless plating process.
